(19) United States
(12) Patent Application Publication
(10) Pub. No.: US 2026/0106614 A1
(43) Pub. Date: Apr. 16, 2026

(54) Contactor Control System

(71) Applicant: Tyco Electronics (Shanghai) Co., Ltd., Shanghai (CN)

(72) Inventors: Jimmy Wang, Shanghai (CN); Xinhui (Robert) Mao, Shanghai (CN); Yisong Wu, Shanghai (CN); Lizhong Wang, Shanghai (CN); Hang An, Shenzhen (CN)

(73) Assignee: Tyco Electronics (Shanghai) Co., Ltd., Shanghai (CN)

(21) Appl. No.: 19/354,892

(22) Filed: Oct. 10, 2025

(30) Foreign Application Priority Data
Oct. 10, 2024 (CN) 202411413633.5

(51) Int. Cl. H03K 17/687; H03K 3/017

(52) U.S. Cl. CPC H03K 17/6871; H03K 3/017

(57) ABSTRACT

A contactor control system includes a drive circuit that has a freewheeling diode and a N-type metal-oxide-semiconductor (MOS) transistor having a drain connected to a positive electrode of the freewheeling diode. The contactor control system includes a control circuit connected to a gate of the N-type MOS transistor and outputting a plurality of pulse width modulation (PWM) waves to the gate. The contactor control system includes a current detection circuit connected to the drive circuit and detecting a holding current of the contactor coil during a holding phase. The current detection circuit feeds back the detected holding current to the control circuit. The control circuit adjusts a duty cycle of the PWM waves output by the control circuit in real time based on a difference between the detected holding current and a predetermined holding current, so that the detected holding current is equal to the predetermined holding current.

### CROSS-REFERENCE TO RELATED APPLICATION

This application claims the benefit of the filing date under 35 U.S.C. § 119(a)-(d) of Chinese Patent Application No. 202411413633.5, filed on Oct. 10, 2024.

### FIELD OF THE INVENTION

The present invention relates to a contactor control system.

### BACKGROUND OF THE INVENTION

A high voltage contactor is a key component of high-voltage distribution. When starting the contactor, a relatively large starting current is required while, when holding it, only a small holding current is needed. A competitive advantage of high-voltage contactors is their small size, which matches customers' demand for miniaturization applications. However, the starting current of the coil of miniaturized high-voltage contactors is relatively high, usually requiring up to 3 A. Many customers have limited power supply, and the supply current generally does not exceed 1.5 A, which cannot meet the current requirements for coil starting. This results in the inability of existing high-voltage contactors to be applied in many customers' products.

In addition, the holding current of the contactor coil is affected by the power supply voltage and operating temperature, which can cause fluctuations in the holding current and affect the reliability of the contactor operation. In order to ensure stable holding current of the contactor coil, voltage compensation and temperature compensation are required for contactor control systems. However, this contactor control system based on voltage compensation and temperature compensation has a complex structure and high cost.

### SUMMARY OF THE INVENTION

A contactor control system includes a drive circuit that has a freewheeling diode and a N-type metal-oxide-semiconductor (MOS) transistor having a drain connected to a positive electrode of the freewheeling diode. The contactor control system includes a control circuit connected to a gate of the N-type MOS transistor and outputting a plurality of pulse width modulation (PWM) waves to the gate. The contactor control system includes a current detection circuit connected to the drive circuit and detecting a holding current of the contactor coil during a holding phase. The current detection circuit feeds back the detected holding current to the control circuit. The control circuit adjusts a duty cycle of the PWM waves output by the control circuit in real time based on a difference between the detected holding current and a predetermined holding current, so that the detected holding current is equal to the predetermined holding current.

### BRIEF DESCRIPTION OF THE DRAWINGS

Features of the present invention will become more apparent by describing in detail exemplary embodiments thereof with reference to the accompanying drawings, in which:

FIG. 1 shows a functional block diagram of a contactor control system according to an exemplary embodiment of the present invention; and

FIG. 2 shows a circuit diagram of a contactor control system according to an exemplary embodiment of the present invention.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

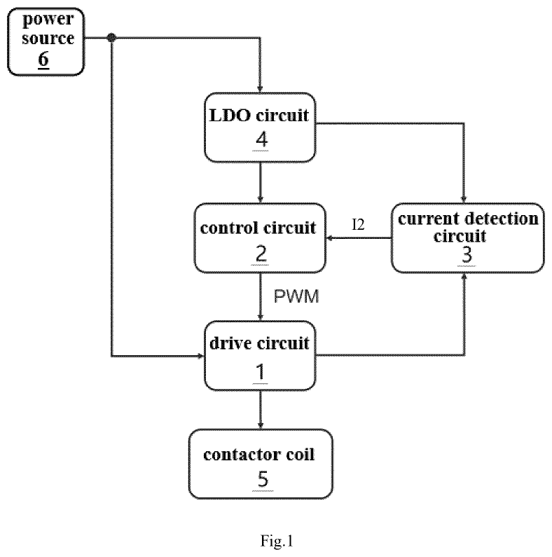

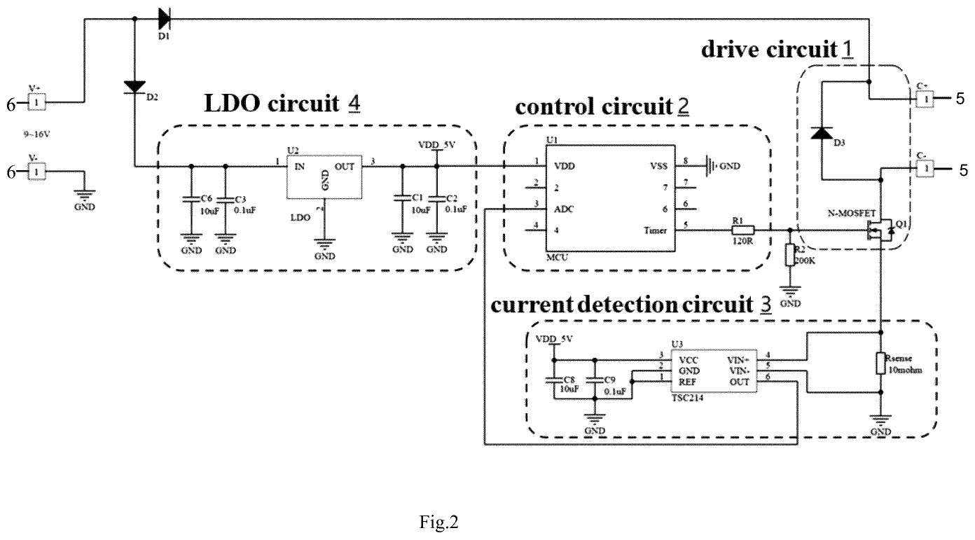

As shown in FIGS. 1 and 2, in an exemplary embodiment of the present invention, a contactor control system is disclosed. The contactor control system includes: a drive circuit 1, a control circuit 2, and a current detection circuit 3. The drive circuit 1, as shown in FIG. 2, includes a freewheeling diode D3 and a N-type metal-oxide-semiconductor (MOS) transistor Q1. The negative electrode of freewheeling diode D3 is used to electrically connect to the positive electrode V+ of power supply 6 and one end C+ of a contactor coil 5, and the positive electrode of freewheeling diode D3 is used to electrically connect to the other end C− of the contactor coil 5. The drain of N-type MOS transistor Q1 is connected to the positive electrode of freewheeling diode D3, and the source of N-type MOS transistor Q1 is used to electrically connect to the negative electrode V− of power supply 6. The control circuit 2 is connected to the gate of N-type MOS transistor Q1 for outputting pulse width modulation (PWM) waves to the gate of N-type MOS transistor Q1. The current detection circuit 3 is connected to the drive circuit 1 and is used to real-time detect the holding current I2 of the contactor coil 5 during the holding phase.

As shown in FIGS. 1 and 2, in the illustrated embodiment, the current detection circuit 3 is connected to the control circuit 2 for feeding back the detected holding current I2 to the control circuit 2. The control circuit 2 adjusts a duty cycle of the PWM wave output by the control circuit 2 in real time based on the difference between the detected holding current I2 and a predetermined holding current, so that the holding current I2 is equal to the predetermined holding current.

The holding current I2 of the contactor coil 5 during the holding phase can be calculated according to the following formula:

$$I 2 = D * Vin / Rcoil , \qquad Formula 1$$

among which Vin is the power supply voltage of power supply 6, and Rcoil is the resistance of contactor coil 5.

When the holding current I2 detected by the current detection circuit 3 is greater than the predetermined holding current, the control circuit 2 gradually reduces the duty cycle D of the PWM wave until the holding current I2 is equal to the predetermined holding current I. When the holding current I2 detected by the current detection circuit 3 is less than the predetermined holding current, the control circuit 2 gradually increases the duty cycle D of the PWM wave until the holding current I2 is equal to the predetermined holding current.

As shown in FIG. 2, in the illustrated embodiment, the current detection circuit 3 includes a sampling resistor Rsense and a current detection chip U3. One end of the sampling resistor Rsense is connected to the source of the N-type MOS transistor Q1, and the other end of the sampling resistor Rsense is grounded (i.e., electrically connected to the negative electrode V− of the power supply 6). The positive input terminal VIN+ of the current detection chip U3 is connected to one end of the sampling resistor Rsense, and the negative input terminal VIN− of the current detection chip U3 is connected to the other end of the sampling resistor Rsense. The control circuit 2 is connected to the output terminal of current detection chip U3, and current detection chip U3 feeds back the detected holding current I2 to the control circuit 2.

In the illustrated embodiment, the current detection chip U3 collects the voltage drop U across the sampling resistor Rsense through its positive input terminal VIN+ and negative input terminal VIN−. The holding current I2 detected by the current detection chip U3 can be calculated according to the following formula:

$$I 2 = U / R , \qquad Formula 2$$

among which U is the voltage drop across the sampling resistor Rsense, and R is the resistance value of the sampling resistor Rsense.

As shown in FIG. 2, in the illustrated embodiment, the control circuit 2 includes a microcontroller U1, and the timer of microcontroller U1 is connected to the gate of N-type MOS transistor Q1. The timer of microcontroller U1 is used to output PWM waves to the gate of N-type MOS transistor Q1.

As shown in FIG. 2, in the illustrated embodiment, the control circuit 2 further includes a resistor R1 and a resistor R2. One end of resistor R1 is connected to the timer of microcontroller U1, and the other end of resistor R1 is connected to the gate of N-type MOS transistor Q1. One end of resistor R2 is connected to the gate of N-type MOS transistor Q1 and the other end of resistor R1, the other end of resistor R2 is grounded. In the illustrated embodiment, the analog-to-digital converter (ADC) of microcontroller U1 is connected to the output terminal of current detection chip U3, used to convert the analog current signal output by current detection chip U3 into a digital current signal.

As shown in FIGS. 1 and 2, in the illustrated embodiment, the contactor control system also includes an LDO circuit 4. The input terminal of LDO circuit 4 is used for electrical connection to power supply 6, and its output terminal is connected to the positive power supply terminal VDD of microcontroller U1 and the power supply terminal VCC of current detection chip U3, for supplying power to microcontroller U1 and current detection chip U3, with a supply voltage of +5V.

As shown in FIGS. 1 and 2, in the illustrated embodiment, the LDO circuit 4 includes a low dropout linear regulator U2, capacitors C3, C6, C1, and C2. The input terminal of the low dropout linear regulator U2 is connected to the positive electrode of the power supply 6, and the output terminal of the low dropout linear regulator U2 is connected to the positive power supply terminal VDD of the microcontroller U1 and the power supply terminal VCC of the current detection chip U3. Capacitor C3 and capacitor C6 are connected in parallel. One ends of capacitor C3 and capacitor C6 are connected to the input terminal of low dropout linear regulator U2, and the other ends of capacitor C3 and capacitor C6 are grounded. Capacitor C1 and capacitor C2 are connected in parallel. One ends of capacitor C1 and capacitor C2 are connected to the output terminal of low dropout linear regulator U2, and the other ends of capacitor C1 and capacitor C2 are grounded.

As shown in FIG. 2, in the illustrated embodiment, the power supply terminal VCC of the current detection chip U3 is connected to the output terminal of the LDO circuit 4, and the ground terminal GND and reference voltage terminal REF of the current detection chip U3 are grounded.

As shown in FIG. 2, in the illustrated embodiment, the current detection circuit 3 also includes capacitors C8 and C9. Capacitors C8 and C9 are connected in parallel. One ends of capacitors C8 and C9 are connected to the power supply terminal VCC of current detection chip U3, and the other ends of capacitors C8 and C9 are connected to the ground terminal GND and reference voltage terminal REF of current detection chip U3.

As shown in FIG. 2, in the illustrated embodiment, LDO circuit 4 also includes a diode D2. The positive electrode of diode D2 is connected to the positive electrode of power supply 6, and the negative electrode of diode D2 is connected to the input terminal of low dropout linear regulator U2.

As shown in FIG. 2, in the illustrated embodiment, the drive circuit 1 further comprises a diode D1. The positive electrode of diode D1 is connected to the positive electrode of power supply 6, and the negative electrode of diode D1 is connected to the negative electrode of freewheeling diode D3.

In the illustrated embodiment, the duty cycle D of the PWM wave output by control circuit 2 to the gate of N-type MOS transistor Q1 during the starting phase of contactor coil 5 is equal to 100%, so that the starting current I1 of contactor coil 5 during the starting phase is not less than the predetermined starting current.

The starting current I1 of the contactor coil 5 during the starting phase can be calculated according to the following formula:

$$I 1 = Vin / Rcoil , \qquad Formula 3$$

among which Vin is the power supply voltage of power supply 6, and Rcoil is the resistance of contactor coil 5.

The duration of the PWM wave with a duty cycle D equal to 100% output by control circuit 2 to the gate of N-type MOS transistor Q1 during the starting phase of contactor coil 5 is not less than the predetermined starting time.

In an exemplary embodiment of the present invention, the predetermined starting current is not less than 1.5 A, for example, the predetermined starting current may be equal to 3 A. The predetermined starting time is not less than 65 milliseconds, for example, the predetermined starting time may be 100 milliseconds.

Please note that FIG. 2 is only an exemplary circuit diagram of the present invention, and the numerical values of each electronic component are only exemplary and can be adjusted according to actual situations. Moreover, the circuit diagram for implementing the functional block diagram shown in FIG. 1 is not limited to the circuit diagram shown in FIG. 2. In the circuit diagram shown in FIG. 2, unless otherwise specified, grounding usually refers to connecting the negative electrode V− of power supply 6.

In the aforementioned exemplary embodiments according to the present invention, the voltage compensation and temperature compensation are achieved by using feedback holding current, simplifying the structure of the contactor control system, reducing the cost of the contactor control system, and ensuring that the contactor coil has a stable holding current.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A contactor control system, comprising:
a drive circuit, including:
a freewheeling diode having a negative electrode electrically connected to a positive electrode of a power source and one end of a contactor coil, and a positive electrode electrically connected to another end of the contactor coil; and
a N-type metal-oxide-semiconductor (MOS) transistor having a drain connected to the positive electrode of the freewheeling diode, and a source electrically connected to a negative electrode of the power supply;
a control circuit connected to a gate of the N-type MOS transistor, the control circuit outputs a plurality of pulse width modulation (PWM) waves to the gate of the N-type MOS transistor; and
a current detection circuit connected to the drive circuit and detecting a holding current of the contactor coil during a holding phase, the current detection circuit is connected to the control circuit for feeding back the holding current to the control circuit, the control circuit adjusts a duty cycle of the PWM waves output by the control circuit in real time based on a difference between the holding current and a predetermined holding current, so that the holding current is equal to the predetermined holding current.

2. The contactor control system according to claim 1, wherein the holding current of the contactor coil during the holding phase is calculated according to the following formula:
$$I 2 = D * Vin / Rcoil ,$$
among which I2 is the holding current, Vin is a power supply voltage of the power supply, and Rcoil is a resistance of the contactor coil.

3. The contactor control system according to claim 2, wherein, when the holding current detected by the current detection circuit is greater than the predetermined holding current I, the control circuit gradually reduces the duty cycle of the PWM waves until the holding current is equal to the predetermined holding current.

4. The contactor control system according to claim 3, wherein, when the holding current detected by the current detection circuit is less than the predetermined holding current, the control circuit gradually increases the duty cycle of the PWM waves until the holding current is equal to the predetermined holding current.

5. The contactor control system according to claim 1, wherein the current detection circuit includes:
a sampling resistor having an end connected to the source of the N-type MOS transistor and another end that is grounded; and
a current detection chip having a positive input terminal connected to the end of the sampling resistor and a negative input terminal connected to the another end of the sampling resistor.

6. The contactor control system according to claim 5, wherein the control circuit is connected to an output terminal of the current detection chip, the current detection chip feeds back the holding current to the control circuit.

7. The contactor control system according to claim 6, wherein the current detection chip collects a voltage drop across the sampling resistor through the positive input terminal and the negative input terminal, the holding current detected by the current detection chip is calculated according to the following formula:
$$I 2 = U / R ,$$
among which U is the voltage drop across the sampling resistor and R is a resistance value of the sampling resistor.

8. The contactor control system according to claim 6, wherein the control circuit includes a microcontroller having a timer connected to the gate of the N-type MOS transistor, the timer of microcontroller outputs the PWM waves to the gate of N-type MOS transistor.

9. The contactor control system according to claim 8, wherein the control circuit includes:
a first resistor having an end connected to the timer of the microcontroller, and another end connected to the gate of N-type MOS transistor; and
a second resistor having an end connected to the gate of N-type MOS transistor and the another end of the first resistor, another end of the second resistor is grounded.

10. The contactor control system according to claim 8, wherein an analog-to-digital converter of the microcontroller is connected to the output terminal of the current detection chip and converts an analog current signal output by the current detection chip into a digital current signal.

11. The contactor control system according to claim 8, further comprising a low dropout regulator (LDO) circuit having an input terminal electrically connected to the power supply, and an output terminal connected to a positive power supply terminal of the microcontroller and a power supply terminal of the current detection chip, for supplying power to the microcontroller and the current detection chip.

12. The contactor control system according to claim 11, wherein the LDO circuit includes:
a low dropout linear regulator having an input terminal connected to the positive electrode of the power source and an output terminal connected to the positive power supply terminal of the microcontroller and the power supply terminal of the current detection chip;
a third capacitor and a sixth capacitor, an end of each is connected to the input terminal of the low dropout linear regulator, and another end of each is grounded; and
a first capacitor and a second capacitor, an end of each is connected to the output terminal of the low dropout linear regulator, and another end of each is grounded.

13. The contactor control system according to claim 11, wherein the power supply terminal of the current detection chip is connected to the output terminal of the LDO circuit, and a ground terminal and a reference voltage terminal of the current detection chip are grounded.

14. The contactor control system according to claim 13, wherein the current detection circuit includes an eighth capacitor and a ninth capacitor, an end of each is connected to the power supply terminal of the current detection chip, and another end of each is connected to the ground terminal and reference voltage terminal of the current detection chip.

15. The contactor control system according to claim 12, wherein the LDO circuit further comprises a second diode having a positive electrode connected to the positive electrode of the power source and a negative electrode connected to the input terminal of the low dropout linear regulator.

16. The contactor control system according to claim 1, wherein the drive circuit further comprises a first diode having a positive electrode connected to the positive electrode of the power source and a negative electrode connected to the negative electrode of the freewheeling diode.

17. The contactor control system according to claim 1, wherein the duty cycle of the PWM waves output by the control circuit to the gate of the N-type MOS transistor during a starting phase of the contactor coil is equal to 100%, so that a starting current of the contactor coil during the starting phase is not less than a predetermined starting current.

18. The contactor control system according to claim 17, wherein the starting current of the contactor coil during the starting phase is calculated according to the following formula:
$$I 1 = Vin / Rcoil ,$$
among which I1 is the starting current, Vin is a power supply voltage of the power source, and Rcoil is a resistance of the contactor coil.

19. The contactor control system according to claim 17, wherein a duration of the PWM waves with a duty cycle equal to 100% output to the gate of the N-type MOS transistor by the control circuit during the starting phase of the contactor coil is not less than a predetermined starting time.

20. The contactor control system according to claim 19, wherein the predetermined starting current is not less than 1.5 A, and the predetermined starting time is not less than 65 milliseconds.
